(19) United States
(12) Patent Application Publication
(10) Pub. No.: US 2025/0390622 A1
(43) Pub. Date: Dec. 25, 2025

(54) COMPUTER-IMPLEMENTED METHODS AND SERVER SYSTEMS FOR GENERATING GRADING DESIGNS

(71) Applicant: SITE SUITE, INC, Soquel, CA (US)

(72) Inventors: Christian Lucas Kjeldsen, Soquel, CA (US); Jordan Cannon, Kenosha, WI (US)

(21) Appl. No.: 19/245,312

(22) Filed: Jun. 21, 2025

Related U.S. Application Data
(60) Provisional application No. 63/663,457, filed on Jun. 24, 2024.

(51) Int. Cl. G06F 30/13

(52) U.S. Cl. CPC G06F 30/13

(57) ABSTRACT

A computer-implemented method for generating grading designs includes accessing existing three-dimensional (3D) surface data of a construction site, and constraint data, from an associated database or one or more electronic devices. The computer-implemented method further includes generating a plurality of definitions of a plurality of respective points in the existing 3D surface data. Furthermore, the computer-implemented method includes generating a variable representing a modifier for a definition, for each point of the plurality of points. Furthermore, the computer-implemented method includes generating one or more linear relationships based at least on the constraint data. The computer-implemented method further includes obtaining a plurality of derived values of the variable, by solving a linear program generated by assembling at least an objective function and the one or more linear relationships. Also, the computer-implemented method includes applying the plurality of derived values to the plurality of respective definitions to generate modified 3D surface data.

### TECHNICAL FIELD

The present disclosure relates to grading design, and more particularly to systems and methods for generating topography grades.

### BACKGROUND

At a construction site, a grading process is performed to reshape the land. The grading process includes adding or removing slopes, raising or lowering ground levels, etc. Depending on the requirement of the construction, the grading should be performed. For example, on the construction site to create a drainage system, proper grading is essential and needs to be properly planned, such that the collected drainage may travel through appropriate channels with the help of gravitation force. Construction includes building roadways, drainage systems, railways, installing some electrical, electronic, or mechanical equipment, solar panels, etc. Proper leveling is essential as the equipment and types of machinery that need to be installed at the site operate and provide the required results only when installed at the desired level or slope.

Proper grading criteria must be set based on the land type, client requirement, safety requirements, etc. Slopes must be carefully designed to prevent erosion, optimize functionality, and ensure long-term stability. Different types of construction projects require specific grading criteria. Currently, a surveyor needs to manually perform the survey of the construction site and the slopes may be adjusted manually based on the survey results. Furthermore, many computer-implemented survey techniques are currently used to survey the construction site and generate a three-dimensional (3D) surface with the existing slopes of the construction sites. Computer-implemented grading design techniques generate an adjusted 3D design surface based on the requirements of a customer. Once the adjusted 3D design information is obtained, tractors equipped with automatic slope adjustment based on the adjusted 3D design surface information may be used to grade the slopes. The computer-implemented grading design technique currently used for grading design is expensive, and requires more complex processing techniques. Further, such techniques are very time-consuming and require a manual process to draw contours and edit elevations using the software.

Therefore, there exists an improved, less time-consuming, cost-effective, and simpler computer-implemented grading design method and server systems for generating the grading design of a topography (i.e., the construction sites).

### SUMMARY

According to an aspect of the present disclosure, there is provided a computer-implemented method for generating grading designs. The computer-implemented method performed by a server system includes accessing existing three-dimensional (3D) surface data of a construction site, and constraint data, from one or more of an associated database or one or more electronic devices. The computer-implemented method further includes generating a plurality of definitions of a plurality of respective points in the existing 3D surface data. Furthermore, the computer-implemented method includes generating a variable representing a modifier for a definition, for each point of the plurality of points. Furthermore, the computer-implemented method includes generating one or more linear relationships based at least on the constraint data. The computer-implemented method further includes obtaining a plurality of derived values, of the variable, for the plurality of respective points. The plurality of derived values is obtained by solving a linear program generated by assembling at least an objective function and the one or more linear relationships. Also, the computer-implemented method includes applying the plurality of derived values to the plurality of respective definitions to generate modified 3D surface data.

According to another aspect of the present disclosure, there is provided a server system for generating grading designs. The server system includes a processor and a memory. The memory includes machine-executable instructions. The machine-executable instructions when executed by the processor, enable the server system to access existing three-dimensional (3D) surface data of a construction site, and constraint data, from one or more of an associated database or one or more electronic devices. The server system is further enabled to generate a plurality of definitions of a plurality of respective points in the existing 3D surface data. Furthermore, the server system is enabled to generate a variable representing a modifier for a definition, for each point of the plurality of points. Furthermore, the server system is enabled to generate one or more linear relationships based at least on the constraint data. The server system is further enabled to obtain a plurality of derived values, of the variable, for the plurality of respective points. The plurality of derived values are obtained by solving a linear program generated by assembling at least an objective function and the one or more linear relationships. Also, the server system is enabled to apply the plurality of derived values to the plurality of respective definitions to generate modified 3D surface data.

According to another aspect of the present disclosure, there is provided a non-transitory computer-readable storage medium including machine-executable instructions. The machine-executable instructions when executed by at least a processor of a server system, enable the server system to perform a computer-implemented method. The computer-implemented method performed by the server system includes accessing existing three-dimensional (3D) surface data of a construction site, and constraint data, from one or more of an associated database or one or more electronic devices. The computer-implemented method further includes generating a plurality of definitions of a plurality of respective points in the existing 3D surface data. Furthermore, the computer-implemented method includes generating a variable representing a modifier for a definition, for each point of the plurality of points. Furthermore, the computer-implemented method includes generating one or more linear relationships based at least on the constraint data. The computer-implemented method further includes obtaining a plurality of derived values, of the variable, for the plurality of respective points. The plurality of derived values are obtained by solving a linear program generated by assembling at least an objective function and the one or more linear relationships. Also, the computer-implemented method includes applying the plurality of derived values to the plurality of respective definitions to generate modified 3D surface data.

In several embodiments of the present disclosure, in relation to the foregoing aspects, the plurality of derived values of the variable include amounts of cut or fill to be performed at the plurality of points. Furthermore, in several embodiments, the one or more linear relationships define constraints including horizontal, vertical, and diagonal slope tolerances, slope-change limits, and a global fill-equals-cut balance, and the objective function indicates minimizing a weighted sum of all adjustments.

### BRIEF DESCRIPTION OF THE DRAWINGS

The following detailed description of illustrative embodiments is better understood when read in conjunction with the appended drawings. For the purpose of illustrating the present disclosure, exemplary constructions of the disclosure are shown in the drawings. However, the present disclosure is not limited to a specific device or a tool and instrumentalities disclosed herein. Moreover, those in the art will understand that the drawings are not to scale. Wherever possible, like elements have been indicated by identical numbers:

FIG. 1 illustrates an example representation of an environment related to at least some example embodiments of the present disclosure;

FIG. 2 is a block diagram of a server system configured to perform grading design, in accordance with an embodiment of the disclosure;

FIG. 3 is a schematic diagram showing a process of generating a grading design using linear programming, in accordance with an embodiment of the disclosure;

FIG. 4 shows an example representation of a Graphical User Interface (GUI) used for generating a grading design using linear programming, in accordance with an embodiment of the disclosure;

FIG. 5A and FIG. 5B illustrate example representations of a three-dimensional (3D) surface of a construction site before and after implementing a generated grading design, respectively, in accordance with an embodiment of the disclosure;

FIG. 5C illustrates an example representation of a top view of points (some points of a plurality of points) in the example representation of FIG. 5A, in accordance with an embodiment of the disclosure;

FIG. 5D illustrates an example representation of a cross-sectional view of the points of FIG. 5C, in accordance with an embodiment of the disclosure;

FIG. 5E illustrates an example representation showing the cross-sectional view of the points of FIG. 5D adjusted after modification, in accordance with an embodiment of the disclosure;

FIG. 6A shows an example representation of the 3D surface of the construction site showing varying slopes before grading design, in accordance with an embodiment of the disclosure;

FIG. 6B shows a cross-section representation of the existing 3D surface of FIG. 6A, before and after grading design, in accordance with an embodiment of the disclosure; and

FIG. 7 is a flow diagram of a method for generating grading design, in accordance with an embodiment of the disclosure.

The drawings referred to in this description are not to be understood as being drawn to scale except if specifically noted, and such drawings are only exemplary in nature.

### DETAILED DESCRIPTION

In the following description, for purposes of explanation, numerous specific details are set forth in order to provide a thorough understanding of the present disclosure. It will be apparent, however, to one skilled in the art that the present disclosure can be practiced without these specific details. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

Reference in this specification to “one embodiment” or “an embodiment” means that a particular feature, structure, or characteristic described in connection with the embodiment is included in at least one embodiment of the present disclosure. The appearance of the phrase “in one embodiment” in various places in the specification does not necessarily refer to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments.

Moreover, although the following description contains many specifics for the purposes of illustration, anyone skilled in the art will appreciate that many variations and/or alterations to said details are within the scope of the present disclosure. Similarly, although many of the features of the present disclosure are described in terms of each other, or in conjunction with each other, one skilled in the art will appreciate that many of these features can be provided independently of other features. Accordingly, this description of the present disclosure is set forth without any loss of generality to, and without imposing limitations upon, the present disclosure.

In the context of the specification, a point in three-dimensional (3D) space is “defined” by coordinates relative to a fixed origin, with common systems including Cartesian, cylindrical, and spherical coordinates. Cartesian coordinates use three perpendicular axes (X, Y, Z) to indicate signed distances from corresponding planes. Cylindrical coordinates define a point using a radial distance from the Z-axis, an azimuthal angle in the XY-plane, and a Z-height. Spherical coordinates specify a point by its radial distance from the origin and two angles: a polar angle from the Z-axis and an azimuthal angle in the XY-plane. The choice of coordinate system may be determined by the specific spatial problem or geometric context.

In the context of the specification, the phrase “three-dimensional (3D) surface data” refers to a digital representation of a topography of a terrain in a construction site, encompassing both its existing (pre-construction) and proposed (post-construction) forms. This 3D surface data can be represented in several ways. One common method involves regularly spaced grids, also known as Digital Elevation Models (DEMs) or Digital Terrain Models (DTMs) when specifically referring to bare-earth surfaces. In this approach, the elevation of the terrains is recorded at predefined, uniform intervals across a horizontal plane, where each cell represents a specific location and contains an elevation value. This structure simplifies data storage and processing, making it efficient for large-scale analysis. However, it might not capture intricate details as effectively in areas with rapidly changing topography if the grid spacing is too wide. Conversely, irregular spacings are employed when a uniform grid is not suitable, often to capture more detail in areas of significant topographic change or to reduce data redundancy in flatter areas. This can manifest as 3D point sets, which are simply collections of individual points, each with a unique X, Y, and Z coordinate representing its location and elevation. These points may be surveyed data, LiDAR scans, or photogrammetry outputs. Furthermore, to create a continuous surface from these irregular points, a common technique is to form a network of interconnected triangles, known as a Triangulated Irregular Network (TIN). A TIN is a non-overlapping, contiguous set of triangles where the vertices of the triangles are the original 3D points.

In the context of the specification, the phrase “constraint data” refers to any limitations, boundaries, or fixed elements that restrict or influence a grading design. Examples include property lines, existing utilities (pipes, cables), setbacks from structures, environmentally protected areas, minimum or maximum slope requirements, and critical elevations for tie-ins to existing infrastructure like roads or drainage systems. Constraint data acts as a set of rules or conditions that the grading design must adhere to, preventing conflicts with existing features and ensuring compliance with regulations and design standards.

In the context of the specification, the phrase “resolution data” refers to a spatial density of generated points within an existing 3D surface. The resolution data dictates the distance between adjacent points in the resulting grid, thereby controlling the granularity of the terrain model used for subsequent grading design. For instance, if the resolution data is set to a value of ‘5’, it means that the generated points in the grid will be spaced 5 units apart from their adjacent counterparts. This unit can represent a distance in millimeters, centimeters, inches, or other relevant linear measurements. Therefore, the resolution data determines the level of detail at which the 3D surface is sampled and processed, influencing the accuracy of grading calculations. Furthermore, the resolution data may specify a minimum feature size that a digital model is capable of representing accurately. For instance, a higher resolution would allow the capture and design of smaller drainage swales or subtle changes in slope that a lower resolution might smooth over. The resolution data may also specify the precision of elevation values, determining the number of decimal places or the smallest unit of vertical measurement that is maintained throughout all of the data. This is particularly important for critical elements where small elevation differences can have significant impacts, such as foundation pads or specialized drainage systems. Furthermore, resolution data might extend to defining the density of break-lines or other linear features that are explicitly modeled in a TIN, ensuring that sharp changes in slope or distinct edges of features (like curbs or retaining walls) are accurately preserved in the digital representation.

In the context of the specification, the phrase “requirement data” refers to functional and performance criteria that the grading design must satisfy. The requirement data can include desired finished elevations for specific areas (e.g., building pads, parking lots), required slopes for drainage, specified material types for different layers, desired compaction rates, and overall site drainage patterns. The requirement data would typically dictate the primary objectives of the grading project, ensuring that the design fulfills its intended purpose, whether it is supporting a structure, managing stormwater, or creating accessible pathways.

In the context of the specification, the phrase “mode data” refers to operational parameters or settings that influence how the grading is performed or analyzed, especially within software applications. This could include the specific grading method employed (e.g., volume balancing, slope-based grading), the units of measurement being used (e.g., meters or feet), the level of detail for calculations, or the display modes for visualization (e.g., cut/fill color mapping, contour line intervals). Mode data essentially configures the environment or methodology for working with the other data types, allowing for different analyses or approaches to the grading problem.

In the context of the specification, the phrase “grid cell” refers to a single, rectangular, or square unit within a regularly spaced grid that covers the entire area of interest. Each grid cell has a defined horizontal dimension (e.g., 1 meter by 1 meter) and is assigned a single elevation value that represents the average, interpolated, or sampled height of the terrain within that specific cell's boundaries. These cells collectively form a continuous raster surface, where the density of the grid (i.e., the size of each cell) directly impacts the resolution and detail of the terrain model; smaller cells provide a more granular and accurate representation of the topography, while larger cells offer a coarser, but more computationally efficient, overview.

In the context of the specification, the term “modifier” refers to a value or a set of values used to perform mathematical operations on coordinates of a point. These operations alter the position, orientation, or scale of the point. The modifier can be a single scalar, a vector, a matrix, or even a more complex function, depending on the desired transformation. For instance, a simple translation modifier would be a vector added to the point's coordinates, shifting its position without changing its orientation or scale. A scaling modifier, on the other hand, would be a scalar or a vector multiplied by the coordinates, expanding or contracting the point's distance from the origin along specific axes. Rotational modifiers are typically represented by rotation matrices or quaternions, which reorient the point around a specific axis or set of axes. The nature of the modifier may be dependent on the mathematical operation it is intended to perform on the coordinates.

When considering cylindrical and spherical coordinate systems, the concept of a “modifier” remains consistent, but its application and interpretation shift due to the different coordinate representations. In a cylindrical coordinate system, a point is defined by (r,θ,z), where r is the radial distance from the z-axis, θ is the azimuthal angle, and z is the height along the z-axis. A modifier here might involve scaling r, shifting θ, or translating z. For example, a modifier to increase the radial distance would involve adding a value to r, while a rotational modifier would involve adding a value to θ. Similarly, in a spherical coordinate system, a point is defined by (ρ,ϕ,θ), where ρ is the distance from the origin, ϕ is the polar angle, and θ is the azimuthal angle. Modifiers in this system would operate on these respective components. Scaling p would move the point closer to or further from the origin, while modifying ϕ and θ would change the point's angular position.

In the context of the specification, the phrase “linear relationship” refers to a statistical or mathematical association where a change in one or more independent variables corresponds to a proportional and constant change in a dependent variable. While commonly visualized between two variables as a straight line on a graph (represented by the equation (y=mx+c), this fundamental concept extends to relationships involving multiple variables. In such cases, one dependent variable is predicted or explained by a linear combination of two or more independent variables, as seen in multiple linear regression models.

By definition, a linear relationship is always of the first order. This means that all variables in the equation are raised to the power of one, and there are no products of variables (e.g., X₁X₂). The linearity is maintained because the relationship is defined by a sum of terms, where each term consists of a constant multiplied by a single variable raised to the power of one.

The generalized form of a linear relationship with multiple variables is expressed as Y=β₀+β₁X₁+β₂X₂+ . . . +βₙXₙ+ϵ. Here, Y is the dependent variable, and X₁, X₂, . . . , Xₙ are the independent variables. β₀, is the intercept, and β₁, β₂, . . . , βₙ are the coefficients (slopes) that quantify the constant rate of change in Y for a unit change in each respective X, assuming other variables remain constant. The term e represents the error. This constant rate of change is a defining characteristic, ensuring that for every consistent shift in the independent variables, the dependent variable responds by a fixed amount.

The direction of the association is also consistent: a positive linear relationship indicates that as independent variables increase, the dependent variable also increases, while a negative linear relationship signifies that as independent variables increase, the dependent variable decreases. Although a simple straight-line visualization is limited to two variables, the multi-variable linear relationship forms a plane in three dimensions and a hyperplane in higher-dimensional spaces. Regardless of the number of variables, the core idea of proportionality and constant change across dimensions remains central to defining a linear relationship, providing a fundamental model for understanding trends and making predictions.

In the context of the specification, the phrase “arbitrary adjacency graph” refers to a construct that uses spatial data points as its vertices and establishes edges (connections) between them without being limited to rigid patterns like regular grids or fixed triangulations. These connections are arbitrary because they are formed based on topological proximity, ensuring nearby points are linked; design relevance, connecting points that define features like road edges or drainage paths; or direct user selection, allowing engineers to enforce specific design relationships.

Embodiments of the present disclosure provide computer-implemented methods and server systems for generating grading designs. An environment for generating grading design employs a distributed system involving users, site experts, customers, and a server system. Multiple users, each with an electronic device, can access a website or a standalone application to input data such as existing three-dimensional (3D) surface data, generate updated surface data, or input project requirements and constraints. The users include designers or experts who provide input for the process of generating the grading design. The electronic devices used for access can be various computing platforms, including desktop computers, smartphones, or tablet computers. The website or the standalone application itself can be an informational portal or a platform offered by construction entities.

Site experts, such as surveyors, also utilize electronic devices to access the same website or the same standalone application. Their primary function involves conducting surveys of construction sites that require grading. The resulting three-dimensional (3D) surface data from the surveys is stored in a database, accessible via communication network. The 3D surface data serves as the baseline for grading operations. Customers, who are typically responsible for the construction site, access the web application or the standalone application using their electronic devices to input their specific requirements for the grading, such as location and type of installation. This requirement data is also stored in the database.

The communication network can be wired, wireless, or a combination, such as the Internet. The website or the standalone application is hosted on a remote server (which may include combinations of web servers, application servers, database servers, compute nodes, load balancers, etc.), and in case of website-based access, the electronic devices may retrieve web pages through standard web browser applications. The server system is configured to generate grading design using linear programming. The server system integrates with the database, which stores all pertinent data, including existing 3D surface data, constraint data, resolution data, requirement data, and mode data. The server system may receive the existing 3D surface data, the constraint data, the resolution data, the mode data from designers, and the requirement data from customers. The data sets may be stored in the database. For generating grading design, the server system may access and process the stored information or may use the data accessed directly from one or more electronic devices.

The existing 3D surface data represents the ungraded surface of the construction site and is generated by site experts using various survey techniques. The constraint data defines the conditions and rules that must be applied to the existing 3D surface data to derive a grading solution. An example of a constraint is setting allowable slopes in specific directions, such as north, south, east, and west, based on customer requirements and construction needs. Additional constraints can include limiting the rate of change of slopes to ensure smooth transitions.

The grading design process involves the server system generating a grid of points on the existing 3D surface data, with point density determined by the resolution data. Every point in generated grid has a definition based on a selected coordinate system. The coordinate system, for instance, may be a Cartesian coordinate system (including X, Y. and Z values for each point), a cylindrical coordinate system, a spherical coordinate system, and the like. Points falling outside the specified area of installation, as defined by the requirement data, are excluded from further processing. For each remaining grid point, a variable representing a modifier for a definition is created. The server system then formulates linear relationships incorporating the variables and the defined constraint data, where constraints establish permissible slopes between adjacent points. For instance, the linear relationships define constraints including horizontal, vertical, and diagonal slope tolerances, slope-change limits, and a global fill-equals-cut balance. The server system then generates a linear program by assembling the linear relationships with an objective function.

Values, of the variable, corresponding to each point, are obtained by solving the linear program. For instance, the derived values of the variable may include amounts of cut or fill to be performed at each point. In that regard, the objective function may indicate minimizing a weighted sum of all adjustments. The derived values are applied to the respective definitions of the points to generate a modified 3D surface data. For instance, the definitions include X, Y, and Z coordinates of the points, and the derived values may include up or down displacements for each point along the Z-axis. In an optimal mode of the mode data, the linear expressions may be solved so that an absolute value of the Z distance (sum of all displacements alone Z axis) that the points would need to move, to conform with at least the constraint data, is minimized.

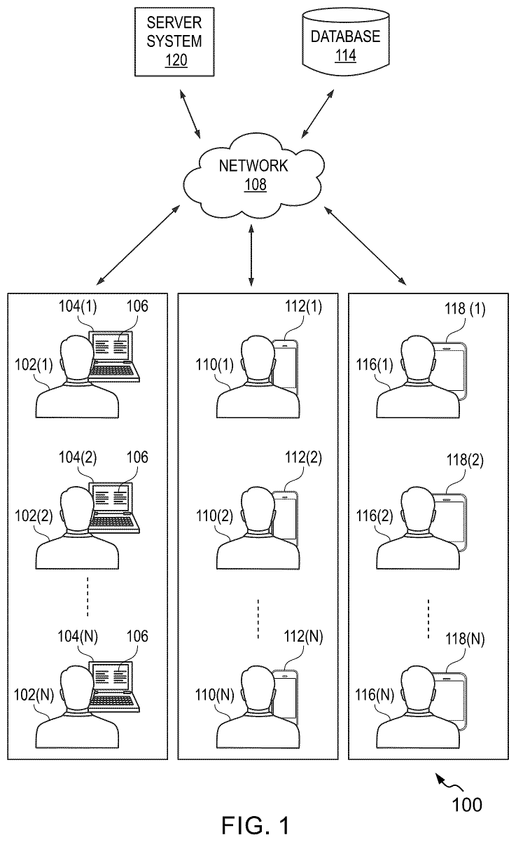

Various embodiments of the present disclosure are described hereinafter with reference to FIG. 1 to FIG. 7.

FIG. 1 illustrates an example representation of an environment 100 related to at least some example embodiments of the present disclosure. The environment 100 depicts a plurality of users (see, 102(1), 102(2), . . . , 102(N)), wherein ‘N’ is a natural number. Further, each of the plurality of users 102(1)-102(N) is associated with an electronic device (see, 104(1), 104(2), . . . , 104(N)), wherein ‘N’ is a natural number. The user (e.g., 102(1)) may be a designer or an expert who inputs data for generating a grading design using linear programming. A user 102(1) of the plurality of users 102(1)-102(N) access a website 106 using an electronic device 104(1) embodied as a desktop computer for a variety of reasons, for example, to obtain existing three-dimensional (3D) surface data, generate updated 3D surface data, input customer details, input constraints, input customer requirements, and the like. It shall be noted that the website 106 is depicted as an informational website for illustration purposes, and the website 106 may correspond to a website offered by constructors, builders, or any other website offered by a private or a public enterprise. Furthermore, the website 106, for at least some of the electronic devices, may be replaced with a standalone application such as a smartphone application or a desktop application. Further, it is noted that the plurality of users 102(1)-102(N) may use any electronic device, such as but not limited to, a smartphone, a tablet computer, a mobile phone, a laptop computer, a personal digital assistant, a web-enabled wearable device and the like, for accessing the website 106.

The environment 100 depicts a plurality of site experts (see, 110(1), 110(2), . . . , 110(N)), wherein ‘N’ is a natural number. Further, each of the plurality of site experts 110(1)-110(N) is associated with an electronic device see, 112(1), 112(2), . . . , 112(N), wherein ‘N’ is a natural number. The plurality of site experts 110(1)-110(N) may be surveyors, tractor operators for leveling the site, and the like. The plurality of site experts 110(1)-110(N) (e.g., surveyors) may perform a survey of the construction site that needs to be graded. The 3D surface data obtained after the survey may be stored in a database 114 associated with the electronic device 112(1), via the communication network 108. A site expert 110(1), of the plurality of site experts 110(1)-110(N), accesses the website 106 using an electronic device 112(1) embodied as a desktop computer for a variety of reasons, such as for example, to input survey information, existing 3D surface data, and the like. It is noted that the plurality of site experts 110(1)-110(N) may use any electronic device, such as but not limited to, a smartphone, a tablet computer, a mobile phone, a laptop computer, a personal digital assistant, a web-enabled wearable device and the like, for accessing the website 106.

The environment 100 further depicts a plurality of customers (see, 116(1), 116(2), . . . , 116(N)), wherein ‘N’ is a natural number. Further, each of the plurality of customers 116(1)-116(N) is associated with an electronic device see, 118(1), 118(2), . . . , 118(N), wherein ‘N’ is a natural number. The plurality of customers 116(1)-116(N) may be persons who own or have possession or are in charge of the construction site to be graded based on the customer requirements. For example, the customer 116(1) may access the web application or mobile application using the electronic device 118(1) to get quotations or details of grading the construction site. The customer 116(1) may input the location, installation, or construction requirement as requirement data. The requirement data may be stored in the database 114 associated with the electronic device 118(1), via the communication network 108. A customer 116(1) of the plurality of customers 116(1)-116(N) may access the website 106 using the electronic device 118(1) embodied as a desktop computer for a variety of reasons, for example, to input customer requirements, customer data, and the like. It is noted that the plurality of customers 116(1)-116(N) may use any electronic device, such as but not limited to, a smartphone, a tablet computer, a mobile phone, a laptop computer, a personal digital assistant, a web-enabled wearable device and the like, for accessing the website 106.

The plurality of electronic devices 104(1)-104(N), 112(1)-112(N), or 118(1)-118(N) may include necessary applications, such as, for example, a web browser application to enable respective a user 102(1), a site expert 110(1), or a customer 118(1) to access the website 106. The website 106 may be hosted on a remote web server and the web browser application may be configured to retrieve one or more web pages associated with the website 106 via communication network 108. In alternate scenario, for some of the electronic devices, the website may be replaced with a standalone mobile application or a desktop application that may directly communicate with a remote application server through an Application Program Interface (API) server, via the communication network 108. Some examples of the communication network 108 may include wired networks, wireless networks, or a combination thereof. Examples of wired networks may include the Ethernet, Local Area Networks (LANs), fiber-optic cable networks, and the like. Examples of wireless networks may include cellular networks like GSM/3G/4G/CDMA-based networks, wireless LANs, Bluetooth or Zigbee networks, and the like. An example of a combination of wired and wireless networks may include the Internet.

The environment 100 depicts a server system 120 (hereinafter also referred to as “the system”) configured to generate a grading design using linear programming. In some embodiments, the database 114 may be integrated with the system 120 and may store existing 3D surface data, constraint data, resolution data, requirement data, and mode data. The system 120 receives the existing 3D surface data, the constraint data, the resolution data, and the mode data from the user 102(1) (e.g., designer) and stores the same in the database 114. The system 120 further receives the requirement data from the customer 116(1) and stores the same in the database 114. To generate the grading design using linear programming, the system 120 accesses the existing 3D surface data, the constraint data, the resolution data, the requirement data, and the mode data from one or more of the database 114 or the one or more electronic devices of plurality of electronic devices 104(1)-104(N), 112(1)-112(N), or 118(1)-118(N).

The existing 3D surface data represents the data related to the ungraded surface of the construction site. The existing 3D surface data may be generated by the site expert (e.g., surveyor) using one or more existing manual or automated techniques. The constraint data represents the conditions and rules that need to be set in the existing 3D surface data and find conforming solutions to grade the existing 3D surface data. An example of the constraint data is setting allowable slopes in the existing 3D surface data. Depending on the requirement data received from the customers 116(1)-116(N), the user 102(1) (e.g., designer) may set the constraint data suitable for the construction based on the customer requirements. In one embodiment of the disclosure, the constraint data includes setting allowable slopes in at least one of the north, south, east, and west directions in the construction site for grading design. Additional constraint data may further be set for a rate of change of the slope in the existing 3D surface data.

The system 120 generates definitions (for instance, coordinates in X-axis, Y-axis, and Z-axis directions) for points in a grid of the existing 3D surface data based on the resolution data. The requirement data provides information related to the location of installation, type of installation, area of installation, etc. The points with the generated definitions are then filtered, for example, by removing points with definitions outside the requirement data (e.g., outside the area of installation), and only the points within the area of installation are considered for further processing. For each point in the grid, a variable representing a modifier for a definition is created. The system 120 is further caused to generate one or more linear relationships with variables, based at least on the constraint data. The constraint data represents the allowable slopes between the points. The system 120 is further caused to obtain a plurality of derived values, of the variable, for the plurality of respective points. The plurality of derived values is obtained by solving a linear program generated by assembling at least an objective function and the one or more linear relationships. Also, the system 120 is caused to apply the plurality of derived values to the plurality of respective definitions to generate a modified 3D surface data.

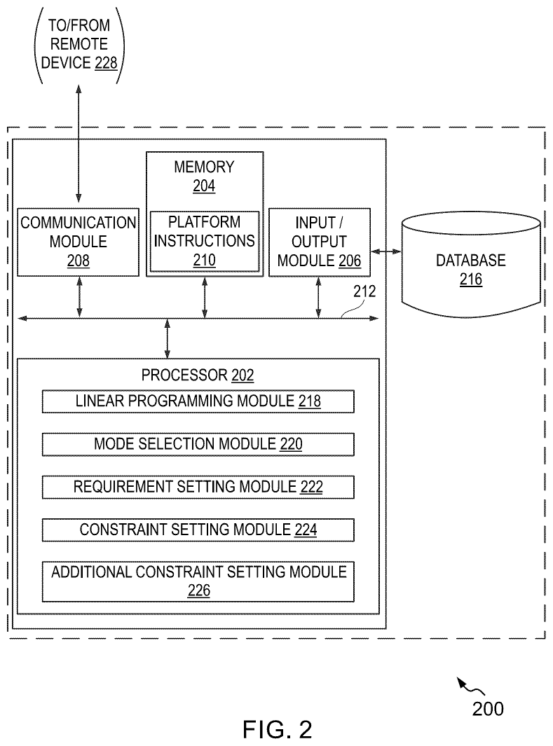

FIG. 2 is a block diagram of a system 200 configured to generate a grading design, in accordance with an embodiment of the disclosure. The system 200 is depicted to include a processor 202, a memory 204, an input/output (I/O) module 206, and a communication module 208. It is noted that although the system 200 is depicted to include the processor 202, the memory 204, the input/output (I/O) module 206, and the communication module 208, in some embodiments, the system 200 may include more or fewer components than those depicted herein. The various components of the system 200 may be implemented using hardware, software, firmware, or any combination thereof. The system 200 depicted in FIG. 2 is similar to the system 120 depicted in FIG. 1.

In one embodiment, the processor 202 may be embodied as a multi-core processor, a single-core processor, or a combination of one or more multi-core processors and one or more single-core processors. For example, the processor 202 may be embodied as one or more of various processing devices, such as a coprocessor, a microprocessor, a controller, a Digital Signal Processor (DSP), a processing circuitry with or without an accompanying DSP, a Graphics Processing Unit (GPU), a System on a Chip (Soc), or various other processing devices including integrated circuits such as, for example, an Application Specific Integrated Circuit (ASIC), a field programmable gate array (FPGA), a microcontroller unit (MCU), a hardware accelerator, a special-purpose computer chip, or the like.

In one embodiment, the memory 204 is capable of storing machine-executable instructions, referred to herein as platform instructions 210. Further, the processor 202 is capable of executing the platform instructions 210. In an embodiment, the processor 202 may be configured to execute hard-coded functionality. In an embodiment, the processor 202 is embodied as an executor of software instructions, wherein the instructions may specifically configure the processor 202 to perform the algorithms and/or operations described herein when the instructions are executed. For example, in at least some embodiments, each component of the processor 202 may be configured to execute instructions stored in the memory 204 for realizing respective functionalities, as will be explained in further detail later.

In an embodiment, the I/O module 206 may include mechanisms configured to receive inputs from and provide outputs to an operator of the system 200. The term ‘operator of the system 200’ as used herein may refer to at least the user 102(1), the site expert 110(1), and the customer 118(1). To enable the reception of inputs and provide outputs to the system 200, the I/O module 206 may include at least one input interface and/or at least one output interface. Examples of the input interface may include, but are not limited to, a keyboard, a mouse, a joystick, a keypad, a touch screen, soft keys, a microphone, and the like. Examples of the output interface may include but are not limited to, a display such as a light-emitting diode display, a thin-film transistor (TFT) display, a liquid crystal display, an Active-Matrix Organic Light-Emitting Diode (AMOLED) display, a microphone, a speaker, a ringer, and the like. In an example embodiment, at least one module of the system 200 may include an I/O circuitry (not shown in FIG. 2) configured to control at least some functions of one or more elements of the I/O module 206, such as, for example, a speaker, a microphone, a display, and/or the like. The processor 202 of the system 200 and/or the I/O circuitry may be configured to control one or more functions of the elements of the I/O module 206 through computer program instructions, for example, software and/or firmware, stored on a memory, for example, the memory 204, and/or the like, accessible to the processor 202 of the system 200.

In some embodiments, the processor 202 and/or other components of the processor 202 may access the storage module 204 using a storage interface (not shown in FIG. 2). The storage interface may include, for example, an Advanced Technology Attachment (ATA) adapter, a Serial ATA (SATA) adapter, a Small Computer System Interface (SCSI) adapter, a RAID controller, a SAN adapter, a network adapter, and/or any component providing the processor 202 and/or other components of the processor 202 with access to the storage module 204.

In one embodiment, the processor 202 includes a linear programming module 218, a mode selection module 220, a requirement setting module 222, a constraint setting module 224, and an additional constraint setting module 226. The mode selection module 220 is configured to at least a) allow the user 102(1) to pre-set at least one mode setting information using the electronic device 104(1); b) allow the user 102(1) to change the mode settings using the electronic device 104(1); c) send at least one available mode details to the electronic device 104(1) of the user 102(1) based on the requirement data received from the customer 116(1); d) receive at least one mode selected by the user 102(1) using the electronic device 104(1) at the time of grading process; e) send mode settings information of the selected mode to the linear programming module 218. For example, the user 102(1) (e.g., designer) may input using a GUI of the electronic device 104(1), at least one mode at which the grading operation of the construction site needs to be performed. Depending on the various requirements different modes may be added to the mode selection module 220. The user 102(1) may further input mode setting values corresponding to each mode. After inputting modes for a construction site, the user may select the mode and its respective setting values that need to be applied to the existing 3D surface data.

The requirement setting module 222 is configured to at least a) allow the user 102(1) to pre-set at least one requirement and its corresponding one or more values; b) send at least one set requirement and its values to the user 102(1); c) receive at least one requirement and its value selected by the user 102(1) based on the requirement data received from the customer 116(1) at the time of grading process; and d) send selected requirement and its values to the linear programming module 218. For example, the user 102(1) (e.g., designer) may input using the GUI of the electronic device 104(1), at least one mode at which the grading operation of the construction site needs to be performed. Depending on the various requirements of the customers, each requirement, and its respective values may be added to the requirement setting module 222. The user 102(1) may input mode setting values corresponding to each mode. After inputting modes for the construction site, the user 102(1) may select the mode and its respective setting values that need to be applied to the existing 3D surface data.

The constraint setting module 224 is configured to at least a) allow the user 102(1) to pre-set at least one constraint and its corresponding one or more values; b) send at least one set of constraints and its values to the user 102(1) at the time of grading process; c) receive at least one constraint and a value of the at least one constraint selected by the user based on the constraint data received from the user at the time of grading process; and d) send selected constraint and its values to the linear programming module 218. The constraint, in that regard, may depend on the requirements of the customer 116(1). In one embodiment, the constraint depends on the requirements of the customers 116(1)-116(N). For example, if the customer wants to install solar panels, then the constraints depend on the type of solar panel being installed and other requirements of the customer 116(1). The constraints for installing solar panels include but are not limited to a 10% to 15% slope at north, east, south, and west. In another embodiment, the constraints for installing solar panels may include but are not limited to a 6% slope in the north, east, and west, and a 10% slope in the south. The additional constraint setting module 226 is configured to limit the rate of change of the slope set using the constraint setting module 224. For example, an additional constraint may be set between three points that will not jump from a −1% to a 5% slope creating a ‘V’ or indent in the surface, if the rate of change is limited to 3%.

The linear programming module 218 is configured to at least a) receive the existing 3D surface data, the constraint data, the resolution data, and the mode data from the user 102(1) (e.g., designer), b) receive the requirement data from the customer 116(1); c) generate a plurality of definitions (coordinates based on a selected coordinate system, such as the Cartesian coordinate system, the cylindrical coordinate system, or the spherical coordinate system) for a plurality of respective points in a grid of the existing 3D surface data based on the resolution data; d) filter the plurality of points by removing one or more points for which the respective generated definitions are not within the user requirement; e) generate a variable representing a modifier for a definition, for each point in the grid; f) generate one or more linear relationships with variables, based on the constraint data (in case of the existing 3D spatial data being in the form of discrete arbitrary 3D spatial data points, the linear programming module 218 arranges the plurality of spatial data points in an arbitrary adjacency graph; furthermore, a linear relationship bounding a difference between two derived variable values corresponds to an edge in the adjacency graph, with a right-hand-side equal to the product of a user-selected tolerance and the Euclidean length of that edge); g) obtain a plurality of derived values, for the variable, by solving a linear program generated by assembling at least an objective function and the one or more linear relationships; and h) generate modified 3D surface data by applying derived values of the variable, to the respective definitions, that conform with at least the constraint data, and in several embodiments, with other data, such as the requirement data, the mode data, the resolution data, and the like. In an example scenario, some points are moved up in the positive z-axis direction and some points are moved down in the negative z-axis direction, to minimize the total movement of the points and achieve optimization.

The memory 204 is any computer-operated hardware suitable for storing and/or retrieving data. In one embodiment, the memory 204 is configured to customer data (e.g., customer Identity (ID), password, etc.), user data (e.g., user ID, password, etc.), site expert data (customer ID, password, etc.), the existing 3D surface data, the constraint data, the resolution data, and the mode data, the requirement data, and the like. The memory 204 may include multiple storage units such as hard drives and/or solid-state drives in a Redundant Array of Inexpensive Disks (RAID) configuration. In some embodiments, the memory 204 may include a Storage Area Network (SAN), and/or a Network Attached Storage (NAS) system. In one embodiment, the memory 204 may correspond to a distributed storage system, wherein individual databases are configured to store custom information, such as user playback event logs.

The various components of the system 200, such as the processor 202, the memory 204, the I/O module 206, the communication module 208, and the memory 204 are configured to communicate with each other via or through a centralized circuit system 212. The centralized circuit system 212 may be various devices configured to, among other things, provide or enable communication between the components of the system 200. In certain embodiments, the centralized circuit system 212 may be a central Printed Circuit Board (PCB) such as a motherboard, a main board, a system board, or a logic board. The centralized circuit system 212 may include other Printed Circuit Assemblies (PCAs) or communication channel media.

In some embodiments, the system 200 is associated with a database 216. The database 216 may be integrated within the memory 204. For example, the memory 204 may include one or more hard disk drives as the database 216. In some examples, the memory 204 may be a buffer for temporarily storing the various data required for grade designing of the construction site. The database 216 may be incorporated in the system 200 or maybe an individual entity connected to the system 200 or maybe the database 216 is stored in a cloud storage. In various non-limiting examples, the database 216 may further include various instructions or firmware data essential for the operation of the system 200. The database 216 depicted in FIG. 2 is similar to the database 114 depicted in FIG. 1.

In an embodiment, the communication module 208 may include a communication circuitry such as for example, a transceiver circuitry including an antenna and other communication media interfaces to facilitate communication between the system 200 and one or more remote entities such as the electronic devices over a communication network (not shown in FIG. 2). The communication module 208 is configured to at least a) receive the constraint data, the resolution data, and the mode data from a remote device 228 (e.g., electronic device 104(1) of the user 102(1)); b) send mode setting information to users 102(1)-102(N) for setting at least one mode for grading design of the construction site; c) send mode setting information to users for setting at least one mode for grading design of the construction site; d) send resolution setting information to users 102(1)-102(N) for setting at least one resolution value for grading design of the construction site; e) receive from the remote device 228 (e.g., electronic device 112(1) of the site expert 110(1)) the existing 3D surface data; and f) receive from the remote device 228 (e.g., electronic device 118(1) of the customer 116(1)), the requirement data from the customer 116(1).

The memory 204 may be embodied as one or more non-volatile memory devices, one or more volatile memory devices, and/or a combination of one or more volatile memory devices and non-volatile memory devices. For example, the memory 204 may be embodied as semiconductor memories, such as flash memory, mask ROM, PROM (programmable ROM), EPROM (erasable PROM), RAM (random access memory), etc., and the like.

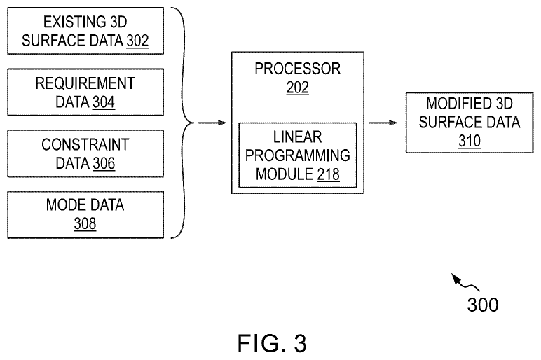

FIG. 3 is a schematic diagram showing a process 300 of generating a grading design using linear programming, in accordance with an embodiment of the disclosure. The database 216 is configured to store at least: a) existing 3D surface data 302 about the construction site from the site experts (e.g., site expert 110(1)), the after performing a manual or automatic survey of the construction site that needs to be graded; b) store the requirement data 304 about the construction site, for example, the purpose of leveling the construction site, the type of installation to be done on the construction site, etc., from the customer 116(1); c) store constraint data 306 about the construction site, for example, the purpose of leveling the construction site, the type of installation to be done on the construction site, etc., from the user 102(1); and d) store mode data 308 about the type of grading the construction site, from the user 102(1).

The linear programming module 218 of the system 200 accesses the existing 3D surface data 302, the constraint data 306 (including the resolution data), the mode data 308, and the requirement data 304 from the database 216. The constraint data 306 includes but is not limited to allowable slopes in each direction, resolution data, etc. In one implementation, the resolution data represents a distance between the points generated in the existing 3D surface data of the construction site. The plurality of definitions (such as the definitions based on the selected coordinate system) for a plurality of respective points in the grid of the existing 3D surface data are generated based on the resolution data. If one or more points are found to be not within the requirement data, for example, based on one or more respective definitions of the one or more points, the plurality of points are filtered based on the requirement data. In that regard, in an example scenario, the one or more points that are found outside of the requirement data are removed from consideration for linear programming.

For each point in the grid, a variable representing a modifier for a definition is generated. The one or more linear relationships are generated with the variables based at least on the constraint data 306. In one embodiment, the constraint data 306 represents the allowable slopes between the points. A plurality of derived values are obtained by solving a linear program generated by assembling at least an objective function and the one or more linear relationships and modified 3D surface data 310 is generated by applying the plurality of derived variable values to the respective definitions of each point. For instance, the points may be moved in positive or negative Z-axis so that the modified 3D surface data 310 conforms with at least the constraint data, and in several embodiments, with other data, such as the requirement data, the mode data, the resolution data, and the like.

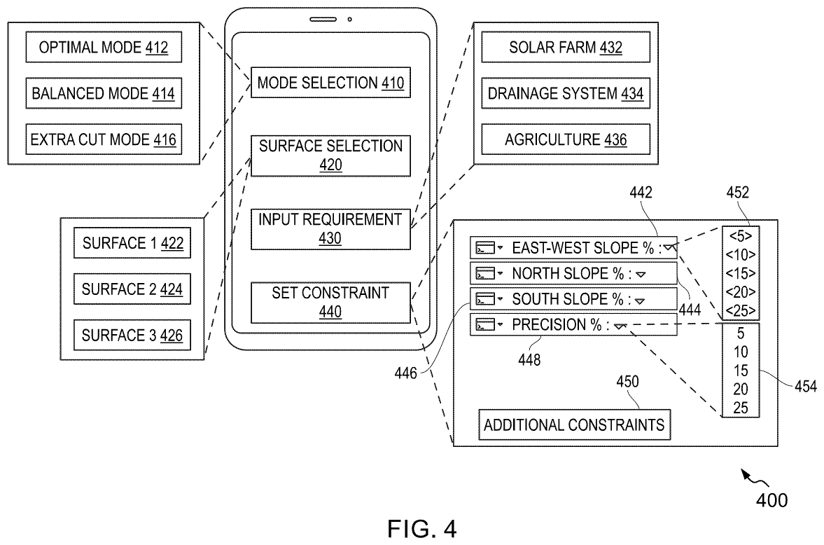

FIG. 4 shows an example representation of a Graphical User Interface (GUI) 400 used for generating a grading design using linear programming, in accordance with an embodiment of the disclosure. A registered user of the system 200 may log in using the user credentials (i.e., user ID and password) to the system 200. The user 102(1), for example, is the designer, who may select grading parameters and values using the GUI 400. The various grading parameters include but are not limited to: a) mode selection 410; b) surface selection 420 c) input requirement 430; and d) set constraint 440. The user may pre-set the various grading parameters and values and the same may be used by the user 102(1) at the time of the grading process, depending on the requirements of the customers, surface, etc.

When the user (i.e., designer) clicks on the mode selection 410 on the GUI 400, the user may select one mode of pre-set modes, not limited to a) optimal mode 412; b) balance mode 414; or c) extra-volume mode 416.

In the optimal mode 412, modification of each one of the plurality of definitions is minimized while the modified 3D surface data 310 is in conformance with the constraint data 306. For instance, in an example scenario, the variable might represent movements of the plurality of points along Z-axis. Therefore, the plurality of points in the grid are moved in such a way that only minimum movement of the points is done to satisfy the set constraints for the optimal mode 412 to conform with at least the constraint data 306, and in several embodiments, with other data, such as the requirement data 304, the resolution data, and the like. In the optimal mode 412, additional constraints (see, 450) may not be set. In some cases, it should be noted that the additional constraints may be set in the optimal mode 412 to ensure a smooth surface with no sharp changes in the slopes. Optimal mode 412 minimizes the sum of the absolute values of the changes in elevation of each point. The modified 3D surface data 310 minimizes the Z distance by moving the points to make the allowable slopes between points conform with at least the constraint data, and in several embodiments, with other data, such as the requirement data, the resolution data, and the like. The optimization minimizes the absolute value of the Z distance that the points would need to conform with at least the constraint data, and in several embodiments, with other data, such as the requirement data, the resolution data, and the like. Some points are moved up in the positive Z-axis direction and some points are moved down in the negative Z-axis direction, to minimize the total movement of the points and achieve optimization.

In the balanced mode 414, the plurality of definitions is modified in a manner that a total volume of earth that is determined to be removed is equal to a total volume of earth that is determined to be filled. Building on the example presented above in respect of the optimal mode 412, the plurality of points in the grid are moved, instead, such that the total volume of points that are cut is equal to the total volume of points that are filled in the grid. In other words, the sum of the positive and negative changes in elevation is equal. Further, in other words, Z-axis adjustments in the positive direction are equal to the Z-axis adjustments in the negative direction. In the extra-volume mode 416, the plurality of definitions is modified in manner that a different between a total volume of earth that is determined to be removed and a total volume of earth that is determined to be filled is equal to a predetermined volume of earth. As an extension to the previous example regarding movement of the plurality of points along the Z-axis (elevation), the difference between the sum of the negative changes in elevation and the sum of the positive changes in elevation is equal to the desired extra cut volume divided by the area of a grid cell.

In addition to the optimal mode 412, the balanced mode 414, and the extra-volume mode 416, there may be additional hybrid modes or modes with slightly different definitions. For instance, an optimal balance mode instructs the website 106 or the application to minimize the overall cut and fill volumes, aiming for a near-zero net earthwork. The optimal mode 412 is highly cost-effective, reducing the need to haul excess material off-site or import additional fill. In contrast, the extra-volume mode 416 might be selected when there is a specific need to generate excess cut material, perhaps for use on another part of the site, or to achieve a lower finished elevation for drainage or flood control purposes. Conversely, an extra fill mode prioritizes maximizing fill, which could be necessary to raise the site for flood protection, create specific landforms, or dispose of material from an adjacent project. These modes are powerful parameters that influence the underlying algorithms, slope adjustments, and how the design ties into existing terrain, enabling engineers to achieve highly targeted and economically viable grading solutions based on specific project requirements and site conditions. The absolute value of changes in elevation represents a positive or negative value of movement along the Z-axis direction to achieve optimization in the movement of each point in the grid.

When the user (i.e., designer) clicks on the surface selection 420 on the GUI 400, the user may select one surface, not limited to “Surface 1” 422, “Surface 2” 424, and “Surface 1” 426. The “Surface 1” 422, “Surface 2” 424, and “Surface 1” represent the land surface with ground, sand, mud, unleveled concrete, and the like.

When the user (i.e., designer) clicks on the input requirement 430 on the GUI 400, the user may select one pre-set requirement information. The input requirement 430, includes but is not limited to the installation of the following on the construction site, solar farm 432, drainage system 434, and agriculture 436. Depending on the input requirement 430, the mode selection 410, the surface selection 420, and constraints may be set in the set constraint 440.

The GUI 400 allows the user 102(1) to set constraints to the existing 3D surface data 302 of the construction site. When the user 102(1) (i.e., designer) clicks on the set constraint 440 on the GUI 400, the user 102(1) may select at least one constraint, including but not limited to slope percentage, for example, east-west slope percentage 442, north slope percentage 444, south slope percentage 446, and resolution percentage 448 (referred to as resolution data). The slope percentage is referred to as the constraint data 306. The east-west slope percentage 442, north slope percentage 444, and south slope percentage 446 may be set with at least one of a set of constraints 452, for example, <5> (i.e., 0 to 5), <10> (i.e., 5 to 10),<15>, (i.e., 10 to 15) <20> (i.e., 15 to 20), and <25> (i.e., 20 to 25). The resolution percentage 448 (referred to as resolution data) representing the distance between the adjacent points in the grid may be of a range 454, including but not limited to 5, 10, 15, 20, and 25 units. Additional constraints 450 maybe added along with the slope percentage and resolution percentage 448, in all modes except optimal mode 412. It should be noted that the settings shown in the GUI 400 are not limited to grading options shown in the GUI 400. For some construction sites, for example, in the construction site of the solar farm 432, other grading steps need to be done in addition to this linear resolution.

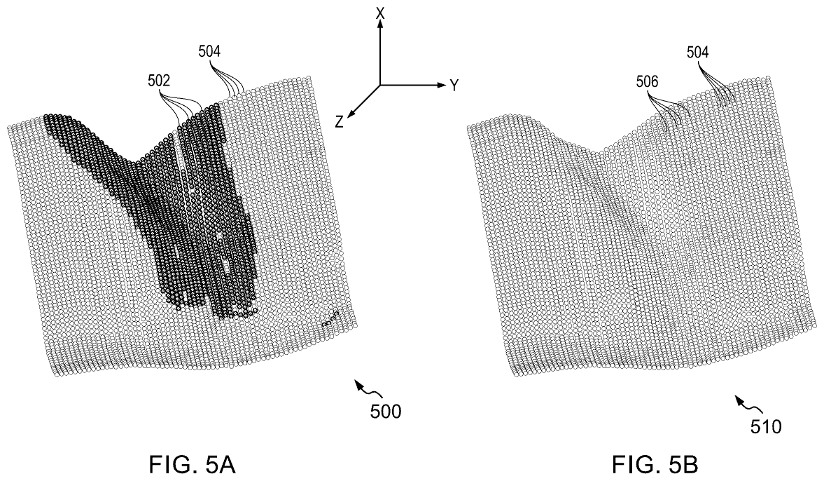

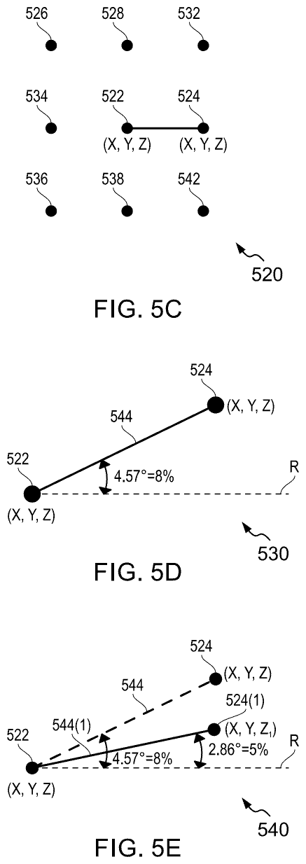

FIG. 5A shows an example representation 500 of a 3D surface (in the form of a 3D grid on the X, Y, and Z-axis) of the construction site before grading design, in accordance with an embodiment of the disclosure. Before grading the design, points 502 need to be leveled (e.g., leveled at 5% north, 5% east, 5% west, and 10% south), while points 504 represent the points that are already in a leveled state within the allowed slope constraint, for the requirement data received from the customer 116(1). FIG. 5B shows an example representation 510 of the 3D surface of the construction site after grading the design using linear programming, in accordance with an embodiment of the disclosure. Based on the constraint data, the space between the points is adjusted to perform grading of the construction site using linear programming. After adjusting the points, the modified 3D surface data 310 obtained is graded as per the customer's requirement. Referring to FIG. 5B, after grading the design, points 502 of FIG. 5A are leveled as points 506 in FIG. 5B, while points 504 represents the leveled points shown in FIG. 5A.

FIG. 5C illustrates an example representation 520 of a top view of points 522, 524, 526, 528, 532, 534, 536, 538, and 542 (i.e., some points of a plurality of points in the 3D grid) in the example representation 500 of FIG. 5A, in accordance with an embodiment of the disclosure. The 3D surface (in the form of the 3D grid on the X, Y, and Z-axis) of the construction site is formed with the plurality of points, based on the resolution data. Some of such plurality of points is represented as points 522, 524, 526, 528, 532, 534, 536, 538, and 542 in FIG. 5C. To understand how the points are moved in the grid based on the resolution data, the points 522, and 524 are considered for illustration in FIG. 5D.

FIG. 5D illustrates an example representation 530 of a cross-sectional view of points 522, and 524 of FIG. 5C, in accordance with an embodiment of the disclosure. As shown in FIG. 5D, the slope between a line 544 connecting the points 522, and 524 with respect to a reference line R is 8%, (i.e., of the value of 4.57). If the constraint is set to make the slope to 5%, (i.e., of the value of 2.86), the Z value (of X, Y, and Z axis shown in FIG. 5D) of the point 524 and/or point 522 are adjusted to achieve the 5% slope between the points 522, and 524. Based on the constraint data, the space between the points 522, and 524 is adjusted using linear programming.

FIG. 5E illustrates an example representation 540 of the cross-sectional view of the points 522, and 524 of FIG. 5D adjusted after grading design, in accordance with an embodiment of the disclosure. As shown in FIG. 5E, a line 544(1) connecting the points 522, and 524(1) represent the points 522, and 524 of FIG. 5D adjusted from Z value (as in FIG. 5D) to Z₁ value (as in FIG. 5E). More specifically, the Z value of the point 524 of FIG. 5D (slope of 8%, (i.e., of the value of 4.57)) is adjusted to Z₁ value, to obtain the adjusted point 524(1) as shown in FIG. 5E, to make the slope to 5%, (i.e., of the value of 2.86). It should be noted that adjustments of the plurality of points in the grid are performed such that the desired slope is achieved by using the derived movements of the plurality of points derived from solving the one or more linear relationships.

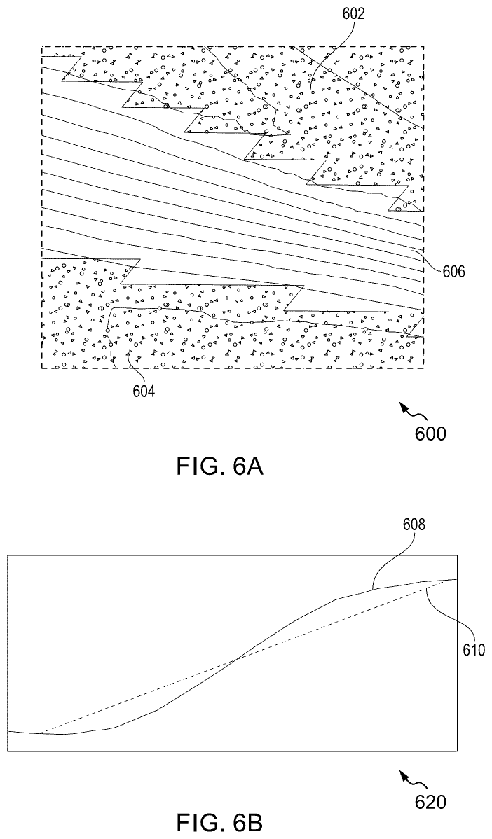

FIG. 6A shows an example representation 600 of the existing 3D surface of the construction site showing contours with varying slopes before grading design, in accordance with an embodiment of the disclosure. The ground surface 602, and 604 represent the ground surface below 5% slope, while the ground surface 606 represents the ground surface above 5% slope. The ground surface 606 is illustrated with contour lines on the example representation 600. Depending on the customer's requirement, the ground surface 602, 604, or 606 may be leveled using linear programming. FIG. 6B shows a cross-section representation 620 of the existing 3D surface of FIG. 6A, before and after grading design, in accordance with an embodiment of the disclosure. The graph 608 represents the existing 3D ground surface, while the graph 610 represents the modified 3D ground surface.

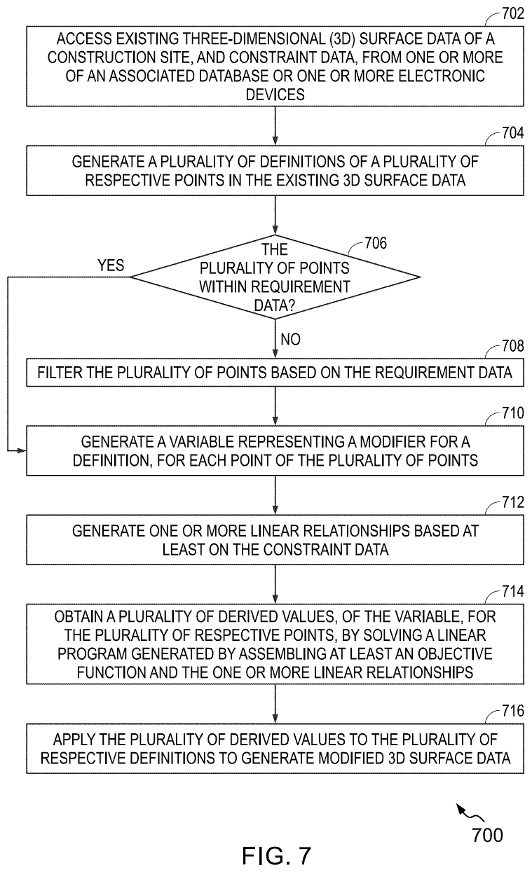

FIG. 7 is a flow diagram of a method 700 for generating a grading design, in accordance with an embodiment of the disclosure. The method 700 depicted in the flow diagram is a computer-implemented method 700 that may be executed by, for example, the system 120 or 200 explained with reference to FIG. 1 and FIG. 2. Operations of the flowchart, and combinations of operations in the flowchart may be implemented by, for example, hardware, firmware, a processor, circuitry, and/or a different device associated with the execution of software that includes one or more computer program instructions. The operations of the method 700 are described herein with help of the system 120. It is noted that the operations of the method 700 may be described and/or practiced by using a system other than the system 120.

At operation 702, from the database 114 associated with the system 120, the existing 3D surface data 302 and the constraint data 306 are accessed by the system 120. In several embodiments, the system 120 may also access the resolution data (see, 448 of FIG. 4), or the mode data 308 from the user 102(1) (e.g., designer). The system 120 may also access the existing 3D surface data 302, the constraint data 306, the resolution data or the mode data 308 directly from one or more electronic devices of the plurality of electronic devices 104(1)-104(N), 112(1)-112(N), or 118(1)-118(N). The operation 702, further includes accessing the requirement data 304 from the customers (e.g., 116(1)). The user 102(1) may use the GUI 400 for inputting the existing 3D surface data 302, the constraint data 306, the resolution data, and the mode data 308, and the same may be stored in the database 114. Similarly, the customers (e.g., 116(1)), may input the requirement data 304 using the electronic device 118(1), and the same may be stored in the database 114. The system 120 accesses the existing 3D surface data 302, the constraint data 306, the resolution data, and the mode data 308 from the database 114.

At operation 704, a plurality of definitions for a plurality of respective points in the grid of the existing 3D surface data 302 are generated based on the resolution data (see, 448 of FIG. 4). In that regard, the plurality of definitions may include Cartesian definitions (X, Y, and Z) definitions of the plurality of points. In several alternate embodiments, the plurality of definitions may include cylindrical or spherical definitions of the plurality of respective points. Furthermore, for example, when the resolution is set as 5 (see, 448 of FIG. 4), the points in the grid are generated such that the distance between the adjacent points is 5 units. The unit refers to a distance in millimeters, centimeters, inches, etc.

At operation 706, the system 120 confirms whether the plurality of generated points is within the requirement data 304. If one or more points are outside the requirement data 304, the plurality of points is filtered based on the requirement data 304, at operation 708. In that regard, in one example scenario, the one or more points outside the requirement data 304 are removed from consideration of linear programming. For example, if the existing 3D surface data 302 is used for solar panel installation, the area of the existing 3D surface data 302 that is used for installing the solar panel (of rectangular shape) alone may be used for generating the points in the grid of the existing 3D surface data 302, while the remaining area may be removed or ignored during the linear programming process.

At operation 710, for each point in the grid, a variable representing a modifier for a definition of the point is generated. For instance, uᵢ may be an upward adjustment for the i-th point, and dᵢ may be a downward adjustment for the i-th point.

At operation 712, the method 700 further includes generating one or more linear relationships with the generated variables, based on the constraint data 306. The constraint data 306 represents the allowable slopes between the points. For instance, the constraint data 306 may include parameters such as eastWestTolerance (tolerance for east-west slope), northSlope Tolerance (tolerance for north slope), southSlopeTolerance (tolerance for south slope), diagonal Tolerance (tolerance for diagonal slope). Furthermore, the constraint data 306 may include optional parameters such as upDowndifference (difference between total upwards and downwards adjustment), and allowedSlopeChange (allowed change in slope between consecutive segments). The constraint data 306 may be defined as given below. For instance, horizontal constraints, vertical constraints, and diagonal constraints may be defined for each point i.

Horizontal slope between the current point and the point to the right may be constrained using relationships (1)-(6).

$${z}_{i}^{′} = {z}_{i} + {u}_{i} - {d}_{i} \qquad ( 1 )$$

$${z}_{right}^{′} = {z}_{right} + {u}_{right} - {d}_{right} \qquad ( 2 )$$

$$\vert {z}_{i}^{′} - {z}_{right}^{′} \vert \leq eastWestTolerance \qquad ( 3 )$$

If allowedSlopeChange is set, the change in slope between left and right neighbors may be constrained.

$$previousHorizontalSlope = {z}_{i}^{′} - {z}_{left}^{′} / {x}_{i} - {x}_{left} \qquad ( 4 )$$

$$newHorizontalSlope = {z}_{r ight}^{′} - {z}_{i}^{′} / {x}_{right} - {x}_{i} \qquad ( 5 )$$

$$\vert newHorizontalSlope - previousHorizontalSlope \vert \leq allowedSlopeChange \qquad ( 6 )$$

Vertical slope between the current point and the point below may be constrained using relationships (7)-(13).

$${z}_{i}^{′} = {z}_{i} + {u}_{i} - {d}_{i} \qquad ( 7 )$$

$${z}_{below}^{′} = {z}_{below} + {u}_{below} - {d}_{below} \qquad ( 8 )$$

$$tolerance = northslopeTolerance if {z}_{below} > {z}_{i} , else southSlopeTolerance \qquad ( 9 )$$

$$\vert {z}_{i}^{′} - {z}_{below}^{′} \vert \leq tolerance \qquad ( 10 )$$

If allowedSlopeChange is set, the change in slope between above and below neighbors may be constrained.

$$previousVerticalSlope = {z}_{i}^{′} - {z}_{above}^{′} / {y}_{i} - {y}_{above} \qquad ( 11 )$$

$$newVerticalSlope = {z}_{b e l o w}^{′} - {z}_{i}^{′} / {y}_{below} - {y}_{i} \qquad ( 12 )$$

$$\vert newVerticalSlope - previousVerticalSlope \vert \leq allowedSlopeChange \qquad ( 13 )$$

Diagonal slope between the current point and the point to the lower right may be constrained using relationships (14)-(16).

$${z}_{i}^{′} = {z}_{i} + {u}_{i} - {d}_{i} \qquad ( 14 )$$

$${z}_{lowerRight}^{′} = {z}_{lowerRight} + {u}_{lowerRight} - {d}_{lowerRight} \qquad ( 15 )$$

$$\vert {z}_{i}^{′} - {z}_{lowerRight}^{′} \vert \leq diagonalTolerance \qquad ( 16 )$$

Diagonal slope between the current point and the point to the lower left may be constrained using relationships (17)-(19).

$${z}_{i}^{′} = {z}_{i} + {u}_{i} - {d}_{i} \qquad ( 17 )$$

$${z}_{lowerLeft}^{′} = {z}_{lowerLeft} + {u}_{lowerLeft} - {d}_{lowerLeft} \qquad ( 18 )$$

$$\vert {z}_{i}^{′} - {z}_{lowerLeft}^{′} \vert \leq diagonalTolerance \qquad ( 19 )$$

Furthermore, if upDownDifference is set, the sum of upwards and downwards adjustments can be constrained using a relationship (20).

$${\sum }_{i} {u}_{i} - {\sum }_{i} {d}_{i} = upDownDifference \qquad ( 20 )$$

Furthermore, an objective function in conformance with the optimal mode 412 of the mode data 308 may be given by a relationship (21).

$${z}_{absolute} = min {\sum }_{i} ( {u}_{i} + {d}_{i} ) \qquad ( 21 )$$

In several alternate embodiments, the objective function (21) may be defined in conformance with other modes such as the balanced mode 414 or the extra-cut mode 416, without departing from the scope of the disclosure.

While the foregoing description assumes a regularly spaced grid of survey points, the plurality of linear relationships (1)-(20) extend to any set of points connected by an adjacency graph (e.g., Delaunay triangulation). In that case, each edge (Pᵢ, Pⱼ) in the graph carries a slope-difference constraint given by a relationship (22).

$$\vert {z}_{i}^{′} - {z}_{j}^{′} \vert = {T}_{ij} \qquad ( 22 )$$

Tᵢⱼ is a tolerance multiplied by the Euclidean distance between points i and j.

Slope-change limits and diagonal-like constraints are likewise imposed on sequences of two edges sharing a node. All other aspects of the plurality of linear relationships (up/down variables, zero net-lift, weighted objective, feedback loop) remain identical.

In case of the existing 3D spatial data being in the form of discrete arbitrary 3D spatial data points, the server system 120 or 200 arranges the plurality of spatial data points in an arbitrary adjacency graph. Furthermore, a linear relationship (see relationship (23)) bounding a difference between two derived variables values corresponds to an edge in the adjacency graph, with a right-hand-side equal to the product of a user-selected tolerance and the Euclidean length of that edge. For each spatial data point Pᵢ, a variable denoted as Δzᵢ, is associated. This variable represents the unknown vertical displacement or change in elevation that must be applied to the current elevation of point Pᵢ to achieve its final, optimized design elevation. That is if Z_{i,initial} is the initial elevation of point Pᵢ, the final elevation Z_{i,final} will be the sum of Z_{i,initial} and Δzᵢ. The objective of the method is to determine the optimal values for allΔzᵢ variables across the entire set of spatial data points.

For an edge connecting spatial data points Pᵢ and Pⱼ, the constraint bounding the difference between their derived variable values, (Δzⱼ−Δzᵢ), can be expressed through the relationship (23).

$$\vert ( {Z}_{i , initial} + Δ {z}_{i} ) - ( {Z}_{j , initial} + Δ {z}_{j} ) \vert \leq {t}_{ij} \times {L}_{ij} \qquad ( 23 )$$

Lᵢⱼ is the Euclidean length of the edge and tᵢⱼ is the user selected tolerance.

For any given edge connecting two spatial data points, say point Pᵢ with coordinates (xᵢ, yᵢ, zᵢ) and point Pⱼ with coordinates (xⱼ, yⱼ, zⱼ), the Euclidean length of the edge, denoted as Lₖⱼ, is computed as the three-dimensional straight-line distance between their initial coordinates, given by relationship (24).

$${L}_{kj} = \sqrt{{( {x}_{j} - {x}_{i} )}^{2} + {( {y}_{j} - {y}_{i} )}^{2} + {( {z}_{j} - {z}_{i} )}^{2}} \qquad ( 24 )$$

The relationship (24) accounts for the actual length of the segment connecting the two points in 3D space, which is critical for accurate slope calculations on irregular meshes. Unlike grid-based systems where distances are often assumed (e.g., cell width or height), irregular meshes necessitate scaling tolerances by the true edge length. For each edge (Pᵢ, Pⱼ) in the arbitrary adjacency graph, a specific tolerance value, tᵢⱼ, is identified. The tolerance value, tᵢⱼ, can be a general design tolerance, or it can be derived from various user-selected precision parameters such as eastWestTolerance, northSlopeTolerance, southSlopeTolerance, or diagonalTolerance based on the primary orientation of the edge or its specific design function. The maximum allowable absolute elevation difference between the adjusted elevations of Pₖ and Pⱼ may be determined using the relationships (22) or (23). This scaling ensures that the slope constraint is precisely applied relative to the actual distance between the connected points, thereby preventing abrupt changes in elevation over short distances and allowing greater flexibility over longer segments, consistent with the desired grade.

For irregular 3D data points or TINs, “neighbor pairs” for enforcing slope-change limits correspond to any two edges that share a common vertex (node). For instance, consider a common vertexPₖ, and two edges originating from the common vertex, Pₖ, would be (Pₘ, Pₖ) and (Pₖ, Pⱼ). To constrain the change in slope, one would first calculate the slope of each individual edge after elevation adjustments using relationships (25) and (26).

$$Slope of edge ( {P}_{m} , {P}_{k} ) : {S}_{mk} = ( {z}_{k}^{′} - {z}_{m}^{′} ) / {L}_{mk} \qquad ( 25 )$$

$$Slope of edge ( {P}_{k} , {P}_{j} ) : {S}_{kj} = ( {z}_{j}^{′} - {z}_{k}^{′} ) / {L}_{kj} \qquad ( 26 )$$

Then, a constraint similar to allowedSlopeChange is applied to the absolute difference between these two adjacent slopes using a relationship (27).

$$\vert {S}_{kj} - {S}_{mk} \vert \leq allowedSlopeChange \qquad ( 27 )$$

This method ensures smoothness across the surface by limiting how abruptly the grade can change as one transitions from one segment to an adjacent segment at a shared point, without relying on fixed “horizontal” or “vertical” neighbors of a grid.

At operation 714, the method 700 further includes obtaining a plurality of derived values, of the variable, for the plurality of respective points. The plurality of derived values are obtained by solving a linear program generated by assembling at least the objective function (21) and the one or more linear relationships (1)-(20), (22)-(27).

At operation 716, the plurality of derived values are applied to the plurality of respective definitions to generate the modified 3D surface data 310. In one example, the modified 3D surface data 310 may generated by modifying Z values of the plurality of definitions (when represented as X, Y, and Z coordinates) with the plurality of derived values of the variable.

For instance, the plurality of derived values of the variable make the allowable slopes between points conform with at least the constraint data, and in several embodiments, with other data, such as the requirement data, mode data, the resolution data, and the like. In an example, in conformance with the optimal mode 412, as given by the relationship (21), the solution of the one or more linear relationships includes the derived values of the variables uᵢ and dᵢ for each point to minimize the absolute value z_{absolute} of the Z distance (a summation of all the values of Z distance for each one of the plurality of points) that the plurality of points would need to move to conform with at least the constraint data. Some points are moved up in the positive Z direction and some points are moved down in the negative Z direction, to minimize the total movement of the points and achieve optimization.

Once the modified 3D surface data 310 is obtained, tractors equipped with automatic slope adjustment techniques may be used to automatically grade the slopes, based on the modified 3D surface data. The computer-implemented grading design technique using linear programming is cheaper and requires more simple processing techniques. Further, the techniques using linear programming are less time-consuming and require a manual process to draw contours and edit elevations using the software.

### Example 1

Table 1 provides example X, Y, and Z definitions of nine (9) points (P0-P8) in existing 3D surface 302 for generating a grading design for the existing 3D surface 302.

TABLE 1

| S. No. | X-Coordinate | Y-Coordinate | Z-Coordinate |
|---|---|---|---|
| P0 | 6257866.5380388033 | 2506523.8572723083 | 598.28563448182229 |
| P1 | 6257886.5380388033 | 2506523.8572723083 | 598.28563448182229 |
| P2 | 6257906.5380388033 | 2506523.8572723083 | 598.4081887891947 |
| P3 | 6257866.5380388033 | 2506503.8572723083 | 599.39796227048248 |
| P4 | 6257886.5380388033 | 2506503.8572723083 | 599.39796227048248 |
| P5 | 6257906.5380388033 | 2506503.8572723083 | 599.50219306057738 |
| P6 | 6257866.5380388033 | 2506483.8572723083 | 599.39796227048248 |
| P7 | 6257886.5380388033 | 2506483.8572723083 | 599.39796227048248 |
| P8 | 6257906.5380388033 | 2506483.8572723083 | 599.50219306057738 |

Table 2 provides constraint data 306 received from one or more electronic devices, such as electronic devices selected from the plurality of electronic devices 104(1)-104(N), 112(1)-112(N), or 118(1)-118(N).

TABLE 2

| S. No. | Constraint Identification | Value |
|---|---|---|
| 1 | eastWestTolerance | 2.00 |
| 2 | northSlopeTolerance | 2.00 |
| 3 | southSlopeTolerance | 2.00 |
| 4 | diagonalTolerance | 2.83 |
| 5 | upDownDifference | 0.00 |
| 6 | allowedSlopeChange | 0.04 |

The values of Table 1 and Table 2 when applied to relationships (1)-(21) generate the up or down movements required at P0-P8 for optimal grading design. The system 120 or 200 may solve linear relationships (1) to (21) using the values from Table 1 and Table 2 by employing a linear programming solver. The following steps may be involved:
1. Defining Variables: For each point i in the grid (P0-P8 as per Table 1), the system 120 or 200 would define two variables: uᵢ (upward adjustment) and dᵢ (downward adjustment).
2. Formulating the Objective Function: The primary goal is to minimize the total absolute Z distance moved by all points. This is represented by the relationship (21). This relationship serves as the objective function that the linear programming solver aims to minimize.
3. Constructing Linear Expressions for Constraints: The server system 120 or 200 would the convert the constraints (allowable slopes and optional parameters from Table 2) into a set of linear inequalities and equalities using the generated variables.
   i. Adjusted Z-coordinates: For each point, the new (adjusted) Z-coordinate (zᵢ′) is defined by the relationships(1) and (7). The initial zᵢ would come from Table 1.
   ii. Horizontal Constraints:
      The absolute difference in adjusted Z-coordinates between a point and its right neighbor must be less than or equal to eastWestTolerance (2.00 from Table 2). This is given by the relationship (3).
      If allowedSlopeChange is set (0.04 from Table 2), the change in horizontal slope between consecutive segments is constrained by the relationship (6), using the relationships (4) and (5) to calculate slopes. The xᵢ and x_{right} values are derived from Table 1.
   iii. Vertical Constraints
      Similar to horizontal, the absolute difference between a point and its below neighbor is constrained by a tolerance (either northSlopeTolerance or southSlopeTolerance, both 2.00 from Table 2), as per the relationship (10). The appropriate tolerance is selected based on the relationship (9). The Z; and Z below values are derived from Table 1.
      If allowedSlopeChange is set, the change in vertical slope between above and below neighbors is constrained by the relationship (13), using the relationships (11) and (12). The yᵢ and y_{above} values are derived from Table 1.
   iv. Diagonal Constraints
      Absolute difference between a point and its lower right neighbor is constrained by diagonalTolerance (2.83 from Table 2), as per the relationship (16).
      Absolute difference between a point and its lower left neighbor is constrained by diagonalTolerance, as per the relationship (19).
   v. Up-Down Difference Constraint: If upDownDifference is set (0.00 from Table 2), the sum of upward and downward adjustments across all points is constrained by the relationship (20).
4. Handling Absolute Values: Relationships involving absolute values (e.g., |A−B|≤C) are converted into two linear inequalities: A−B≤C and A−B≥−C.
5. Non-negativity Constraints: Implicitly, uᵢ and dᵢ must be non-negative values, as they represent upward and downward adjustments. The solver would include constraints uᵢ≥0 and dᵢ≥0.
6. Linear Programming Solver: Once all the variables, the objective function, and the linear constraints (equalities and inequalities) are formulated, the system 120 or 200 feeds the entire derivation into a linear programming solver. The specialized algorithm (e.g., Simplex method or Interior-Point methods) will efficiently find the optimal values for uᵢ and dᵢ that minimize the objective function (z_{absolute}) while satisfying all the defined constraints. The output would be the optimized uᵢ and dᵢ values for each point, which are then used to calculate the adjusted Z-coordinates (zᵢ′).

The results are listed in Table 3.

TABLE 3

| S. No. | z (original) | moveUpBy | moveDownBy | z (adjusted) |
|---|---|---|---|---|
| P0 | 598.29 | 0.0 | 0.0 | 598.29 |
| P1 | 598.29 | 0.0 | 0.0 | 598.29 |
| P2 | 598.42 | 0.29 | 0.0 | 598.71 |
| P3 | 599.40 | 0.0 | 0.15 | 599.25 |
| P4 | 599.40 | 0.0 | 0.16 | 599.24 |
| P5 | 599.50 | 0.0 | 0.0 | 599.50 |
| P6 | 599.40 | 0.012 | 0.0 | 599.41 |
| P7 | 599.40 | 0.0 | 0.0 | 599.40 |
| P8 | 599.50 | 0.0 | 0.0 | 599.50 |

In one embodiment, the present disclosure is used in the field of at least partially automating civil engineering grading design using linear programming algorithms and streamlining the design process. The allowable slopes are inputted between points in the form of resolution data and the constraints are linear programmed to generate the grading design with the correct slopes. By using linear programming, a grid of X, Y, and Z points is generated from a 3D surface of the existing ground, and the constraints are set. Further, the allowable relationship between the points is assigned as 5% and the absolute value of the displacement along Z axis may be optimized while also being in conformance with at least the constraint data, and in several embodiments, with other data, such as the requirement data, the resolution data, and the like. Targeting the absolute value ensures that the points will move the minimum amount of distance in the Z-axis direction to satisfy the 5% constraint, therefore optimizing the volume created between the proposed points and the existing points. The modified 3D surface may then be made from the points that moved.

Embodiments of the present disclosure offer several advantages in the construction domain. A primary benefit is the optimization of earthwork volumes, which translates directly into cost savings. By precisely calculating the minimum Z-axis movement required for each point to satisfy design constraints, the embodiments can achieve an optimal balance between cut and fill material. This reduction in net earthwork volume minimizes the need for hauling excess material off-site or importing additional fill, which are significant cost drivers in construction projects. The ability to select different operational modes provides a flexible approach to earthwork management, allowing project managers to align the grading process with specific project objectives and resource availability.

Another advantage is enhanced precision and consistency in the final graded surface. Traditional manual methods of grading design can introduce human error and inconsistencies, leading to deviations from design specifications. The systems, by applying mathematical algorithms consistently across the entire site, ensure that slopes, elevations, and transitions adhere precisely to the specified constraints and resolution data. This accuracy reduces the likelihood of rework, improves the quality of the finished product, and contributes to the long-term performance and functionality of the constructed elements, such as foundations, roads, and drainage systems. The detailed grid-based approach with variable elevation adjustments allows for fine-tuning of the terrain to meet exacting standards.

Furthermore, the computer-implemented generation of a grading design contributes to increased efficiency and reduced project timelines. The process of generating grading plans, which can be laborious and time-consuming when performed manually, is significantly accelerated through linear programming. The system can rapidly process large datasets, iterate through various solutions, and identify a design as per a desired mode much faster than human designers. This speed translates into quicker turnaround times for design phases, enabling earlier commencement of earthwork operations and contributing to overall project schedule adherence. It frees up human designers to focus on higher-level design challenges and critical decision-making rather than repetitive calculations.

Also, the computer-implemented approach provides improved decision-making capabilities and adaptability. By integrating various data types, such as existing 3D surface data, requirements, constraints, resolution, and operational modes, the embodiments offer a comprehensive framework for design. The ability to input and modify these parameters, such as adjusting allowable slopes or changing grading modes, allows for rapid evaluation of different scenarios. This analytical capability supports informed decision-making by designers and project stakeholders, enabling them to assess the impact of various design choices on cost, earthwork balance, and overall site performance before any physical work commences. The capacity to adjust point elevations to satisfy complex linear relationships means it can handle intricate grading requirements that would be challenging to manage manually.

Various embodiments of the disclosure, as discussed above, may be practiced with steps and/or operations in a different order, and/or with hardware elements in configurations, which are different than those which, are disclosed. Therefore, although the disclosure has been described based on these exemplary embodiments, it is noted that certain modifications, variations, and alternative constructions may be apparent and well within the spirit and scope of the disclosure.

Although various exemplary embodiments of the disclosure are described herein in a language specific to structural features and/or methodological acts, the subject matter defined in the appended claims is not necessarily limited to the specific features or acts described above. Rather, the specific features and acts described above are disclosed as exemplary forms of implementing the claims.

What is claimed is:

1. A computer-implemented method for generating grading designs, comprising:
accessing, by a server system, existing three-dimensional (3D) surface data of a construction site, and constraint data, from one or more of an associated database or one or more electronic devices;
generating, by the server system, a plurality of definitions of a plurality of respective points in the existing 3D surface data;
generating, by the server system, a variable representing a modifier for a definition, for each point of the plurality of points;
generating, by the server system, one or more linear relationships based at least on the constraint data;
obtaining, by the server system, a plurality of derived values, of the variable, for the plurality of respective points, wherein the plurality of derived values are obtained by solving a linear program generated by assembling at least an objective function and the one or more linear relationships; and
applying, by the server system, the plurality of derived values to the plurality of respective definitions to generate modified 3D surface data.

2. The computer implemented method as claimed in claim 1, wherein the existing 3D surface data is provided in form of a plurality of spatial data points arranged in an arbitrary adjacency graph, and a linear relationship bounding a difference between two derived values corresponds to an edge in the arbitrary adjacency graph, with a right-hand-side equal to a product of a user-selected tolerance and a Euclidean length of the edge.

3. The computer-implemented method as claimed in claim 1, wherein the constraint data comprises resolution data, and the plurality of definitions are generated based on the resolution data.

4. The computer-implemented method as claimed in claim 1, further comprising:
accessing, by the server system, requirement data from one or more of the associated database and the one or more electronic devices; and
filtering, by the server system, the plurality of points based at least on the requirement data.

5. The computer-implemented method as claimed in claim 1, further comprising accessing, by the server system, mode data from the associated database or the one or more electronic devices, wherein the one or more linear relationships are solved in conformance with the mode data.

6. The computer-implemented method as claimed in claim 5, wherein the mode data is selected from a group comprising of one or more pre-set modes, the one or more pre-set modes comprising:
an optimal mode wherein modification of each one of the plurality of definitions is minimized while the modified 3D surface data is in conformance with the constraint data;
a balanced mode wherein the plurality of definitions is modified in a manner that a total volume of earth that is determined to be removed is equal to a total volume of earth that is determined to be filled; and
an extra-volume mode wherein the plurality of definitions is modified in manner that a different between a total volume of earth that is determined to be removed and a total volume of earth that is determined to be filled is equal to a predetermined volume of earth.

7. The computer-implemented method as claimed in claim 1, wherein the plurality of definitions comprises X, Y, and Z coordinates of the plurality of respective points, and the plurality of derived values minimizes an absolute value of the Z distance that the plurality of respective points would need to move to conform with at least the constraint data.

8. A server system for generating grading designs, comprising:
a processor; and
a memory comprising machine-executable instructions, the machine-executable instructions when executed by the processor, enable the server system to:
access existing three-dimensional (3D) surface data of a construction site, and constraint data, from one or more of an associated database or one or more electronic devices,
generate a plurality of definitions of a plurality of respective points in the existing 3D surface data,
generate a variable representing a modifier for a definition, for each point of the plurality of points,
generate one or more linear relationships based at least on the constraint data,
obtain a plurality of derived values, of the variable, for the plurality of respective points, wherein the plurality of derived values are obtained by solving a linear program generated by assembling at least an objective function and the one or more linear relationships, and
apply the plurality of derived values to the plurality of respective definitions to generate modified 3D surface data.

9. The server system as claimed in claim 8, wherein the constraint data comprises resolution data, and the server system is enabled to generate the plurality of definitions based on the resolution data.

10. The server system as claimed in claim 8, wherein the existing 3D surface data is provided in form of a plurality of spatial data points arranged in an arbitrary adjacency graph, and a linear relationship bounding a difference between two derived values corresponds to an edge in the arbitrary adjacency graph, with a right-hand-side equal to a product of a user-selected tolerance and a Euclidean length of the edge.

11. The server system as claimed in claim 8, wherein the server system is further enabled to:
access requirement data from the associated database or the one or more electronic device; and
filter the plurality of points based at least on the requirement data.

12. The server system as claimed in claim 8, wherein the server system is further enabled to access mode data from the associated database or the one or more electronic devices, the server system is enabled to solve the one or more linear relationships in conformance with the mode data.

13. The server system as claimed in claim 12, wherein the mode data is selected from a group consisting of one or more pre-set modes, the one or more pre-set modes comprising:
an optimal mode wherein modification of each one of the plurality of definitions is minimized while the modified 3D surface data is in conformance with the constraint data;
a balanced mode wherein the plurality of definitions is modified in a manner that a total volume of earth that is determined to be removed is equal to a total volume of earth that is determined to be filled; and
an extra-volume mode wherein the plurality of definitions is modified in manner that a different between a total volume of earth that is determined to be removed and a total volume of earth that is determined to be filled is equal to a predetermined volume of earth.

14. The server system as claimed in claim 8, wherein the plurality of definitions comprises X, Y, and Z coordinates of the plurality of respective points, and the plurality of derived values minimizes an absolute value of the Z distance that the plurality of respective points would need to move to conform with at least the constraint data.

15. A non-transitory computer-readable storage medium for generating grading designs, comprising machine-executable instructions that, when executed by at least a processor of a server system, enable the server system to perform a computer-implemented method comprising:
accessing existing three-dimensional (3D) surface data of a construction site, and constraint data, from one or more of an associated database or one or more electronic devices;
generating a plurality of definitions of a plurality of respective points in the existing 3D surface data;
generating a variable representing a modifier for a definition, for each point of the plurality of points;
generating one or more linear relationships based at least on the constraint data;
obtaining a plurality of derived values, of the variable, for the plurality of respective points, wherein the plurality of derived values are obtained by solving a linear program generated by assembling at least an objective function and the one or more linear relationships; and
applying the plurality of derived values to the plurality of respective definitions to generate modified 3D surface data.

16. The non-transitory computer-readable storage medium as claimed in claim 15, wherein the constraint data comprises resolution data, and the server system is enabled to generate the plurality of definitions based on the resolution data.

17. The non-transitory computer-readable storage medium as claimed in claim 15, wherein the existing 3D surface data is provided in form of a plurality of spatial data points arranged in an arbitrary adjacency graph, and a linear relationship bounding a difference between two derived values corresponds to an edge in the arbitrary adjacency graph, with a right-hand-side equal to a product of a user-selected tolerance and a Euclidean length of the edge.

18. The non-transitory computer-readable storage medium as claimed in claim 15, wherein the server system is further enabled to:
access requirement data from the associated database or the one or more electronic device; and
filter the plurality of points based at least on the requirement data.

19. The non-transitory computer-readable storage medium as claimed in claim 15, wherein:
the server system is further enabled to access mode data from the associated database or the one or more electronic devices,
the server system is enabled to solve the one or more linear relationships in conformance with the mode data, and
the mode data is selected from a group consisting of one or more pre-set modes, the one or more pre-set modes comprising:
an optimal mode wherein modification of each one of the plurality of definitions is minimized while the modified 3D surface data is in conformance with the constraint data;
a balanced mode wherein the plurality of definitions is modified in a manner that a total volume of earth that is determined to be removed is equal to a total volume of earth that is determined to be filled; and
an extra-volume mode wherein the plurality of definitions is modified in manner that a different between a total volume of earth that is determined to be removed and a total volume of earth that is determined to be filled is equal to a predetermined volume of earth.

20. The non-transitory computer-readable storage medium as claimed in claim 15, wherein the plurality of definitions comprises X, Y, and Z coordinates of the plurality of respective points, and the plurality of derived values minimizes an absolute value of the Z distance that the plurality of respective points would need to move to conform with at least the constraint data.
